(19) United States
(12) Patent Application Publication
(10) Pub. No.: US 2020/0161613 A1
(43) Pub. Date: May 21, 2020

(54) STANDARD ENERGY STORAGE CONTAINER PLATFORM

(71) Applicant: Flex Ltd., Singapore (SG)

(72) Inventors: Alejandro Fabian Schnakofsky, Windermere, FL (US); Carl J. Little, Camas, CA (US)

(21) Appl. No.: 16/686,838

(22) Filed: Nov. 18, 2019

Related U.S. Application Data
(63) Continuation of application No. 15/476,281, filed on Mar. 31, 2017.
(60) Provisional application No. 62/316,155, filed on Mar. 31, 2016.

(51) Int. Cl. H01M 2/10; H01M 10/627; H01M 10/613; H01M 10/663; H01M 2/20

(52) U.S. Cl. CPC H01M 2/1077; H01M 10/627; H05K 7/20945; H01M 10/663; H01M 2/206; H01M 10/613

(57) ABSTRACT

Embodiments of the disclosure provide an adaptable energy storage container that is interoperable with a plurality of battery types. For example, the disclosure provides an adaptable energy storage container design and method of use that is readily interoperable, e.g. physically and electrically, with a variety of battery types. The container and other components can be assembled into an energy storage platform. For example, the container can substantially enclose a plurality of battery strings within the platform. A central, internal gangway can provide fast access to battery modules and other components within the container. The strings of batteries, each comprising a plurality of battery modules, can be disposed within the container, substantially parallel to each other, and on either side of the central, internal gangway. The battery strings and battery modules therein can be accessed by the gangway through a door at an end of the container.

### CROSS REFERENCE TO RELATED APPLICATION

The present application claims the benefits of and priority of U.S. patent application Ser. No. 15/476,281 filed Mar. 31, 2017, entitled “Standard Energy Storage Container Platform”, which claims the benefits of and priority, under 35 U.S.C. § 119(e), to U.S. Provisional Application No. 62/316,155 filed Mar. 31, 2016 by Schnakofsky et. al. and entitled “Standard Energy Storage Container Platform” of which the entire disclosure is incorporated herein by reference for all purposes.

### FIELD OF THE DISCLOSURE

Embodiments of the present disclosure relate generally to methods and systems for a battery energy storage system and more particularly to an adaptable energy storage container that is interoperable with a plurality of battery types.

### BACKGROUND

Large-scale energy storage is commonly used to store electrical energy on a large scale within an electrical power grid. Using such storage, electrical energy can be stored during times when production exceeds consumption, and returned to the grid when production falls below consumption. Such energy storage is especially useful with renewable energy sources such as wind power, tidal power, solar power which can be intermittent or non-constant. A Battery Energy Storage System (BESS) is one form of large-scale energy storage which uses batteries for energy storage of a few kilowatts (kW) up to the megawatt (MW) range. In a typical BESS, the batteries are housed in warehouses or in containers inverters convert the stored Direct Current (DC) provided by the batteries to Alternating Current (AC) to be utilized by the power grid.

With continuing development and reliance on renewable energy sources, among other reasons, the utility scale energy storage market is expected to grow. As battery costs reach their limit, the focus has turned to system and integration costs. For the most part, today's BESS have been deployed for pilot and Proof Of Concept (POC) projects. As such, today's BESS supply chain and fabrication has been built to support a small number of build. Because of this, the engineered shelter for BESS represents an expensive portion of the overall system costs and requires a long lead time which limits production scalability. Hence, there is a need for improved methods and systems for improved battery energy storage systems.

### BRIEF SUMMARY

Embodiments of the disclosure provide systems and methods for an adaptable energy storage container and platform that is interoperable with a plurality of battery types. For example, the disclosure provides an adaptable energy storage container design and method of use that is readily interoperable, e.g. physically and electrically, with a variety of battery types (e.g. lithium-ion, Nickel-cadmium (NiCd), Nickel-metal hydride (NiMh), Li-ion polymer, and other batteries known to those skilled in the art). Embodiments described herein provide a standard engineered container that can have a flexible layout, provide specified thermal management, meet a weight distribution budget, and provide zone 4 seismic structural integrity. The adaptable container and platform described herein can leverage volumes, standardize manufacturing processes, and scale to various size projects. Energy and power density of the platform can be increased by more fully utilizing the space inside the container. Additionally, integration times can be reduced by enabling the roll-in of complete sub assemblies, e.g., batteries, controls, protections, etc. A central, internal gangway can provide fast access to battery modules and other components within the container.

According to one embodiment, a container for an energy storage platform can comprise a bottom portion forming a deck of the container, a top portion disposed above the bottom portion and forming a roof of the container, and four sides extending from the bottom portion of the container to the top portion of the container. The bottom portion, the four sides, and the top portion can form a substantially rectangular box substantially enclosing an interior portion of the container with two parallel sides of the four sides forming a length side of the rectangular box and another two parallel sides of the four sides forming a width side of the rectangular box, and wherein the length side of the rectangular box is longer than the width side. A central, internal gangway on the deck of the container can extend a length of the container substantially parallel to the two parallel sides forming the length side of the rectangular box. A plurality of equipment racks can be disposed within the interior portion of the container substantially parallel and opposite to each other on each side of the gangway and adjacent to the two parallel sides forming the length side of the rectangular box. One or more of the racks can each be adapted to accept and retain a plurality of different types of battery strings

In some cases, one of the sides forming the width side of the rectangular box can comprise a door providing access to the gangway and the interior of the container. Additionally or alternatively, at least one of the sides forming the length side of the rectangular box can comprise one or more doors providing access to the equipment racks adjacent to the at least one of the sides. In some cases, the one or more doors of the at least one of the sides forming the length side of the rectangular box can comprise a plurality of doors. In some cases, both of the sides forming the length side of the rectangular box can comprise one or more doors providing access to the equipment racks. In some cases, the one or more doors of each of the sides forming the length side of the rectangular box can comprise a plurality of doors.

According to another embodiment, an energy storage platform can comprise a container. The container can comprise a bottom portion forming a deck of the container, a top portion disposed above the bottom portion and forming a roof of the container, and four sides extending from the bottom portion of the container to the top portion of the container. The bottom portion, the four sides, and the top portion can form a substantially rectangular box substantially enclosing an interior portion of the container with two parallel sides of the four sides forming a length side of the rectangular box, and another two parallel sides of the four sides forming a width side of the rectangular box, and wherein the length side of the rectangular box is longer than the width side. A central, internal gangway on the deck of the container can extend a length of the container substantially parallel to the two parallel sides forming the length side of the rectangular box. A plurality of equipment racks can be disposed within the interior portion of the container. The equipment racks can be disposed substantially parallel and opposite to each other on each side of the gangway and adjacent to the two parallel sides forming the length side of the rectangular box. A plurality of battery strings, each battery string comprising a plurality of battery modules, can be mounted in the plurality of equipment racks.

The battery modules of each battery string can comprise a battery type, the battery type comprising one or more of lithium-ion, nickel-cadmium, nickel-metal hydride, lithium-ion polymer, or lead-acid. In some cases, at least one of the battery strings can comprise battery modules of a different battery type from battery modules of one or more other battery strings of the plurality of battery strings. In some cases, each battery string can further comprise one or more battery string protection circuits and one or more battery string control circuits mounted in the equipment racks.

Each battery string can be further connected with one or more protection circuits, one or more battery string connections, and a main bus or conductors for the energy storage platform. One or more other components mounted in one or more of the equipment racks. The one or more other components mounted in one or more of the equipment racks can comprise one or more of a power distribution cabinet, a Heating Ventilation and Air Conditioning (HVAC) system, a fire suppression system, internal lighting, or a master controller.

### BRIEF DESCRIPTION OF THE DRAWINGS

FIG. 1 is a diagram illustrating an isometric view of an energy storage platform container according to one embodiment of the present disclosure.

FIG. 2 is a diagram illustrating a cross-sectional top view of an assembled energy storage platform according to one embodiment of the present disclosure.

FIG. 3 is a block diagram illustrating components of an energy storage platform according to one embodiment of the present disclosure.

FIG. 4 is a diagram illustrating a cross-sectional side view of an energy storage platform container according to one embodiment of the present disclosure.

FIG. 5 is a diagram illustrating a cross-sectional side view of an energy storage platform according to another embodiment of the present disclosure.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the second reference label.

### DETAILED DESCRIPTION

In the following description, for the purposes of explanation, numerous specific details are set forth in order to provide a thorough understanding of various embodiments disclosed herein. It will be apparent, however, to one skilled in the art that various embodiments of the present disclosure may be practiced without some of these specific details. The ensuing description provides exemplary embodiments only, and is not intended to limit the scope or applicability of the disclosure. Furthermore, to avoid unnecessarily obscuring the present disclosure, the preceding description omits a number of known structures and devices. This omission is not to be construed as a limitation of the scopes of the claims. Rather, the ensuing description of the exemplary embodiments will provide those skilled in the art with an enabling description for implementing an exemplary embodiment. It should however be appreciated that the present disclosure may be practiced in a variety of ways beyond the specific detail set forth herein.

While the exemplary aspects, embodiments, and/or configurations illustrated herein show the various components of the system collocated, certain components of the system can be located remotely, at distant portions of a distributed network, such as a LAN and/or the Internet, or within a dedicated system. Thus, it should be appreciated, that the components of the system can be combined in to one or more devices or collocated on a particular node of a distributed network, such as an analog and/or digital telecommunications network, a packet-switch network, or a circuit-switched network. It will be appreciated from the following description, and for reasons of computational efficiency, that the components of the system can be arranged at any location within a distributed network of components without affecting the operation of the system.

Furthermore, it should be appreciated that the various links connecting the elements can be wired or wireless links, or any combination thereof, or any other known or later developed element(s) that is capable of supplying and/or communicating data to and from the connected elements. These wired or wireless links can also be secure links and may be capable of communicating encrypted information. Transmission media used as links, for example, can be any suitable carrier for electrical signals, including coaxial cables, copper wire and fiber optics, and may take the form of acoustic or light waves, such as those generated during radio-wave and infra-red data communications.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted that the terms “comprising,” “including,” and “having” can be used interchangeably.

The term “automatic” and variations thereof, as used herein, refers to any process or operation done without material human input when the process or operation is performed. However, a process or operation can be automatic, even though performance of the process or operation uses material or immaterial human input, if the input is received before performance of the process or operation. Human input is deemed to be material if such input influences how the process or operation will be performed. Human input that consents to the performance of the process or operation is not deemed to be “material.”

The term “computer-readable medium” as used herein refers to any tangible storage and/or transmission medium that participate in providing instructions to a processor for execution. Such a medium may take many forms, including but not limited to, non-volatile media, volatile media, and transmission media. Non-volatile media includes, for example, NVRAM, or magnetic or optical disks. Volatile media includes dynamic memory, such as main memory. Common forms of computer-readable media include, for example, a floppy disk, a flexible disk, hard disk, magnetic tape, or any other magnetic medium, magneto-optical medium, a CD-ROM, any other optical medium, punch cards, paper tape, any other physical medium with patterns of holes, a RAM, a PROM, and EPROM, a FLASH-EPROM, a solid state medium like a memory card, any other memory chip or cartridge, a carrier wave as described hereinafter, or any other medium from which a computer can read. A digital file attachment to e-mail or other self-contained information archive or set of archives is considered a distribution medium equivalent to a tangible storage medium. When the computer-readable media is configured as a database, it is to be understood that the database may be any type of database, such as relational, hierarchical, object-oriented, and/or the like. Accordingly, the disclosure is considered to include a tangible storage medium or distribution medium and prior art-recognized equivalents and successor media, in which the software implementations of the present disclosure are stored.

A “computer readable signal” medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device. Program code embodied on a computer readable medium may be transmitted using any appropriate medium, including but not limited to wireless, wireline, optical fiber cable, RF, etc., or any suitable combination of the foregoing.

The terms “determine,” “calculate,” and “compute,” and variations thereof, as used herein, are used interchangeably and include any type of methodology, process, mathematical operation or technique.

It shall be understood that the term “means” as used herein shall be given its broadest possible interpretation in accordance with 35 U.S.C., Section 112, Paragraph 6. Accordingly, a claim incorporating the term “means” shall cover all structures, materials, or acts set forth herein, and all of the equivalents thereof. Further, the structures, materials or acts and the equivalents thereof shall include all those described in the summary of the disclosure, brief description of the drawings, detailed description, abstract, and claims themselves.

Aspects of the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.” Any combination of one or more computer readable medium(s) may be utilized. The computer readable medium may be a computer readable signal medium or a computer readable storage medium.

In yet another embodiment, the systems and methods of this disclosure can be implemented in conjunction with a special purpose computer, a programmed microprocessor or microcontroller and peripheral integrated circuit element(s), an ASIC or other integrated circuit, a digital signal processor, a hard-wired electronic or logic circuit such as discrete element circuit, a programmable logic device or gate array such as PLD, PLA, FPGA, PAL, special purpose computer, any comparable means, or the like. In general, any device(s) or means capable of implementing the methodology illustrated herein can be used to implement the various aspects of this disclosure. Exemplary hardware that can be used for the disclosed embodiments, configurations, and aspects includes computers, handheld devices, telephones (e.g., cellular, Internet enabled, digital, analog, hybrids, and others), and other hardware known in the art. Some of these devices include processors (e.g., a single or multiple microprocessors), memory, nonvolatile storage, input devices, and output devices. Furthermore, alternative software implementations including, but not limited to, distributed processing or component/object distributed processing, parallel processing, or virtual machine processing can also be constructed to implement the methods described herein.

Examples of the processors as described herein may include, but are not limited to, at least one of Qualcomm® Snapdragon® 800 and 801, Qualcomm® Snapdragon® 610 and 615 with 4G LTE Integration and 64-bit computing, Apple® A7 processor with 64-bit architecture, Apple® M7 motion coprocessors, Samsung® Exynos® series, the Intel® Core™ family of processors, the Intel® Xeon® family of processors, the Intel® Atom™ family of processors, the Intel Itanium® family of processors, Intel® Core® i5-4670K and i7-4770K 22 nm Haswell, Intel® Core® i5-3570K 22 nm Ivy Bridge, the AMD® FX™ family of processors, AMD® FX-4300, FX-6300, and FX-8350 32 nm Vishera, AMD® Kaveri processors, Texas Instruments® Jacinto C6000™ automotive infotainment processors, Texas Instruments® OMAP™ automotive-grade mobile processors, ARM® Cortex™-M processors, ARM® Cortex-A and ARM926EJ-S™ processors, other industry-equivalent processors, and may perform computational functions using any known or future-developed standard, instruction set, libraries, and/or architecture.

In yet another embodiment, the disclosed methods may be readily implemented in conjunction with software using object or object-oriented software development environments that provide portable source code that can be used on a variety of computer or workstation platforms. Alternatively, the disclosed system may be implemented partially or fully in hardware using standard logic circuits or VLSI design. Whether software or hardware is used to implement the systems in accordance with this disclosure is dependent on the speed and/or efficiency requirements of the system, the particular function, and the particular software or hardware systems or microprocessor or microcomputer systems being utilized.

In yet another embodiment, the disclosed methods may be partially implemented in software that can be stored on a storage medium, executed on programmed general-purpose computer with the cooperation of a controller and memory, a special purpose computer, a microprocessor, or the like. In these instances, the systems and methods of this disclosure can be implemented as program embedded on personal computer such as an applet, JAVA® or CGI script, as a resource residing on a server or computer workstation, as a routine embedded in a dedicated measurement system, system component, or the like. The system can also be implemented by physically incorporating the system and/or method into a software and/or hardware system.

Although the present disclosure describes components and functions implemented in the aspects, embodiments, and/or configurations with reference to particular standards and protocols, the aspects, embodiments, and/or configurations are not limited to such standards and protocols. Other similar standards and protocols not mentioned herein are in existence and are considered to be included in the present disclosure. Moreover, the standards and protocols mentioned herein and other similar standards and protocols not mentioned herein are periodically superseded by faster or more effective equivalents having essentially the same functions. Such replacement standards and protocols having the same functions are considered equivalents included in the present disclosure.

Embodiments of the disclosure provide an adaptable energy storage container that is interoperable with a plurality of battery types. For example, the disclosure provides an adaptable energy storage container design and method of use that is readily interoperable, e.g. physically and electrically, with a variety of battery types (e.g. lithium-ion, Nickel-cadmium (NiCd), Nickel-metal hydride (NiMh), Li-ion polymer, and other batteries known to those skilled in the art). Embodiments described herein provide a standard engineered container that can have a flexible layout, provide specified thermal management, meet a weight distribution budget, and provide zone 4 seismic structural integrity.

The container and other components can be assembled into an energy storage platform. For example, the container can substantially enclose a plurality of battery strings within the platform. A central, internal gangway can provide fast access to battery modules and other components within the container. The strings of batteries, each comprising a plurality of battery modules, can be disposed within the container, substantially parallel to each other, and on either side of the central, internal gangway. The battery strings and battery modules therein can be accessed by the gangway through a door at an end of the container. The battery strings and battery modules therein can also be accessed through one or more doors along an outside of the container on a side of the battery strings opposite the central, internal gangway. Other components of the platform disposed within the container can include, but are not limited to, electrical busses and/or connections for the battery strings and/or modules within each string, electrical controllers for one or more of the battery strings, over voltage, over current and/or other electrical protections for the battery strings, power distribution conductors and controls for electrical power within the container, a Heating Ventilation and Air Conditioning (HVAC) system for temperature control within the container, fire suppression system, lighting within the container, etc.

Various additional details of embodiments of the present disclosure will be described below with reference to the figures. While the flowcharts will be discussed and illustrated in relation to a particular sequence of events, it should be appreciated that changes, additions, and omissions to this sequence can occur without materially affecting the operation of the disclosed embodiments, configuration, and aspects.

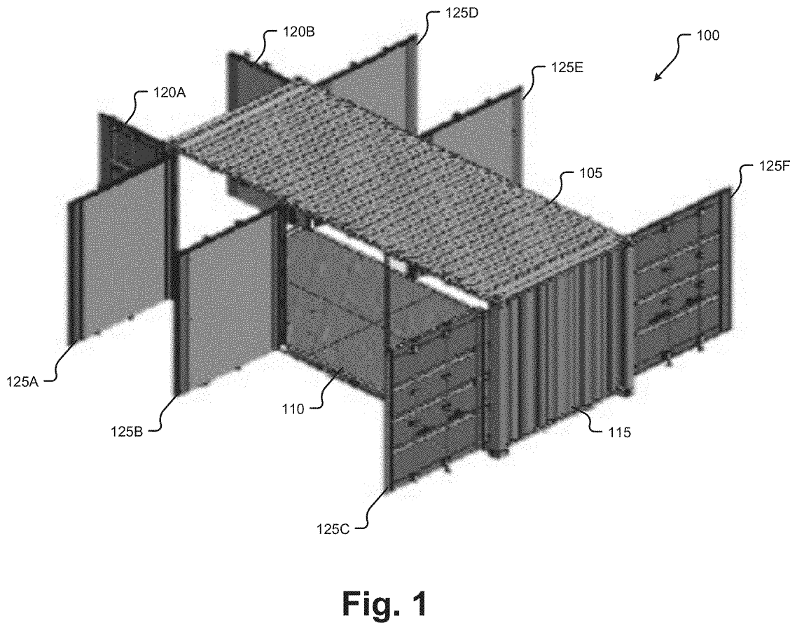

FIG. 1 is a diagram illustrating an isometric view of an energy storage platform container according to one embodiment of the present disclosure. As illustrated in this example, the container 100 for an energy storage platform can comprise a substantially rectangular box, i.e., a rectangular cuboid. The container 100 can comprise a top portion 105 or roof, a bottom portion 110 or floor or deck, and four sides to enclose the contents of the container 100 when the energy storage platform is assembled. It should be understood that the materials used to construct the container 100 can vary widely depending upon the exact implementation. However, it is contemplated that the materials will be sufficient to provide structural integrity and rigidity to container as well as the assembled energy storage platform as will be described in greater detail below. Therefore, steel, aluminum, and/or other metals may be used to form beams, struts, panels, doors, and other members of the container 100. In some cases, these materials can be combined or replaced with others, in part or in total, depending upon the exact implementation. A wide range of such variations are contemplated and considered to be within the scope of the present disclosure.

According to one embodiment, one or more sides of the container 100 may be fixed or sealed while other one or more sides may comprise doors or removeable covers or panels for assembly of the energy storage platform or to provide access to components within the container 100 after assembly. For example, one end 115 of the container 100 may be closed or sealed while another end, in this example the opposite end, can comprise a set of doors 10A and 120B through which the interior of the container 100 can be accessed. The other sides, i.e., the long sides of the container as shown here, can either or both also comprise one or more doors 125A-125E or removeable panels to provide further access to the interior of the container 100 or contents within the container when or after the energy storage platform is assembled.

According to one embodiment and as will be described in greater detail below, the container 100 can also comprise a central, internal gangway (not shown here) along the bottom portion 110 or deck of the container. The container 100 can also comprise a number of equipment racks (not shown here) disposed within the container 100, substantially parallel to each other, and on either side of the central, internal gangway, i.e., along and adjacent to the long sides of the container as illustrated here. The racks can be accessed by the gangway through the doors 120A and 120B at an end of the container 100. According to one embodiment, the racks can also be accessed through one or more doors 125A-125F along an outside of the container 100, i.e., along the long side of the container as illustrated here, and adjacent to the racks. As will be described in greater detail below, the racks can be adapted to accept and retain one or more strings of batteries and other components of the energy storage platform when assembled. The batteries used can be a variety of battery types including, but not limited to, lithium-ion, nickel-cadmium (NiCd), nickel-metal hydride (NiMh), lithium-ion polymer, lead-acid, and other batteries known to those skilled in the art.

Stated another way, a container 100 for an energy storage platform can comprise a bottom portion 110 forming a deck of the container 100, a top portion 105 disposed above the bottom portion 110 and forming a roof of the container 100, and four sides 115, 120A and 120B, 125A-125C, and 125D-125F extending from the bottom portion 110 of the container 100 to the top portion 105 of the container 100. The bottom portion 110, the four sides 115, 120A and 120B, 125A-125C, and 125D-125F, and the top portion 105 can form a substantially rectangular box substantially enclosing an interior portion of the container with two parallel sides 125A-125C and 125D-125F of the four sides forming a length side of the rectangular box and another two parallel sides 115 and 120A and 120B of the four sides forming a width side of the rectangular box, and wherein the length side of the rectangular box is longer than the width side. A central, internal gangway on the deck 110 of the container can extend a length of the container substantially parallel to the two parallel sides 125A-125C and 125D-125F forming the length side of the rectangular box. A plurality of equipment racks can be disposed within the interior portion of the container 100 substantially parallel and opposite to each other on each side of the gangway and adjacent to the two parallel sides 125A-125C and 125D-125F forming the length side of the rectangular box. One or more of the racks can each be adapted to accept and retain a plurality of different types of battery strings.

In some cases, one of the sides 120A and 120B forming the width side of the rectangular box can comprise a door providing access to the gangway and the interior of the container 100. Additionally or alternatively, at least one of the sides 125A-125C forming the length side of the rectangular box can comprise one or more doors providing access to the equipment racks adjacent to the at least one of the sides. In some cases, the one or more doors of the at least one of the sides 125A-125C forming the length side of the rectangular box can comprise a plurality of doors. In some cases, both of the sides 125A-125C and 125D-125F forming the length side of the rectangular box can comprise one or more doors providing access to the equipment racks. In some cases, the one or more doors of each of the sides 125A-125C and 125D-125F forming the length side of the rectangular box can comprise a plurality of doors.

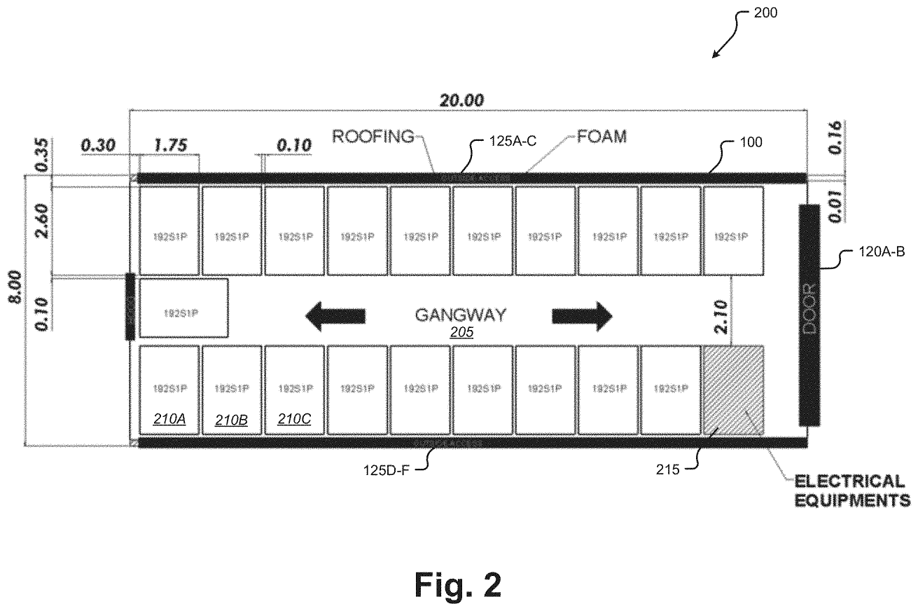

FIG. 2 is a diagram illustrating a cross-sectional top view of an assembled energy storage platform according to one embodiment of the present disclosure. As illustrated in this example, the assembled energy storage platform 200 can comprise a container 100 as described above. As also described above, the container 100 can comprise a central, internal gangway 205, walkway, or corridor along the bottom portion 110 or deck of the container 100. The container 100 can also comprise a number of equipment racks (not shown here) disposed within the container 100, substantially parallel to each other, and on either side of the central, internal gangway 205, i.e., along and adjacent to the long sides of the container as illustrated here. The racks can be accessed by the gangway 205 through the doors 120A and 120B at an end of the container 100. According to one embodiment, the racks can also be accessed through one or more doors 125A-125C and/or 125D-125F along an outside of the container 100, i.e., along the long side of the container as illustrated here, and adjacent to the racks. As will be described in greater detail below, the racks can be adapted to accept and retain one or more strings of batteries 210A-210C and other components of the energy storage platform when assembled. The batteries used can be a variety of battery types including, but not limited to, lithium-ion, nickel-cadmium (NiCd), nickel-metal hydride (NiMh), lithium-ion polymer, lead-acid, and other batteries known to those skilled in the art. Additionally, one or more racks along either or both sides of the gangway 205 can contain electrical equipment 215 and/or other components of the assembled energy storage platform 200. As will be described in greater detail below, the electrical equipment 215 and/or other components can include, but are not limited to, electrical busses and/or connections for the battery strings and/or modules within each string, electrical controllers for one or more of the battery strings, over voltage, over current and/or other electrical protections for the battery strings, power distribution conductors and controls for electrical power within the container, a Heating Ventilation and Air Conditioning (HVAC) system for temperature control within the container, fire suppression system, lighting within the container, etc.

A number of dimensions, in feet, are included here for illustrative purposes. For example, a length of the energy storage platform 200, i.e., along the sides comprising doors 125A-125C and 125D-125F, is shown as being approximately 20 feet. Similarly, the width of the energy storage platform 200, i.e., along the side including doors 120A and 120B, is shown to be approximately 8 feet. Further, the gangway 205 is shown to be approximately 2 feet wide while the battery strings 210A-210C or racks are shown to be approximately 1.75 wide and approximately 2.6 feet deep with a gap of approximately 0.1 feet between each. However, it should be noted and understood that these dimensions are provided by way of example only and are not intended to limit the scope of the present disclosure. These dimensions can vary widely depending upon the exact implementation without departing from the scope of the present disclosure and these dimensions are provided only to demonstrate one such possible implementation.

Regardless of the exact dimensions, assembly of the energy storage platform 200 can begin with fabricating and/or obtaining an empty container 100 as described above. The racks inside of the container 100 can be accessed via the doors 120A and 120B at one end and the central, interior gangway 205. Assembled battery strings 210A-210C, each comprising one or more battery modules, as well as electrical equipment 215 and/or other components can be slid or carried into the container 100 through the doors 120A and 120B and along the gangway 205 and mounted into the racks along either or both sides of the gangway 205.

Additionally, the one or more battery 210A-210C, electrical equipment 215, and/or other components can be accessed through the doors 125A-125C and/or 125D-125F along the sides of the container 100 before, during, or after the components are being or have been mounted into the racks to facilitate the electrical connection and/or mechanical mounting of the components into the racks. For example, and according to one embodiment, the battery modules comprising each battery string 210A-210C and/or the electrical equipment may have electrical terminals, connectors, conductors, etc. on a side opposite the gangway 205 and accessible through the doors 125A-125C and/or 125D-125F along the sides of the container 100 to electrically connect these components and/or mechanically secure them in the racks. In such cases, the doors 125A-125C and/or 125D-125F may be lined on the inside with a non-conductive foam or other electrical insulating material to prevent short circuits and/or other hazardous conditions.

This arrangement not only provides a safety enhancement by keeping electrical conductors away from individuals using the gangway 205 of the container 100 but also allows the gangway 205 and the overall width of the electrical storage platform 200 to be narrower, i.e., more dense. This also allows the platform 200 to be unmanned, limiting personnel exposure to hazards (high voltage, arc flash, fire, etc.) stemming from the batteries. The platform 200 can be unmanned yet maintainable and operable from the outside by employing an open side design as described which allows access to the equipment through the side doors 125A-125F without having to enter the container 100. At the same time, this layout increases energy density by allocating as much space as possible to the batteries inside the container 100 without having to make space provisions for workspace. In some cases, the gangway 205 may even be eliminated so no personnel are exposed to hazards inside the platform space for the gangway 205 can be utilized to pack more batteries inside.

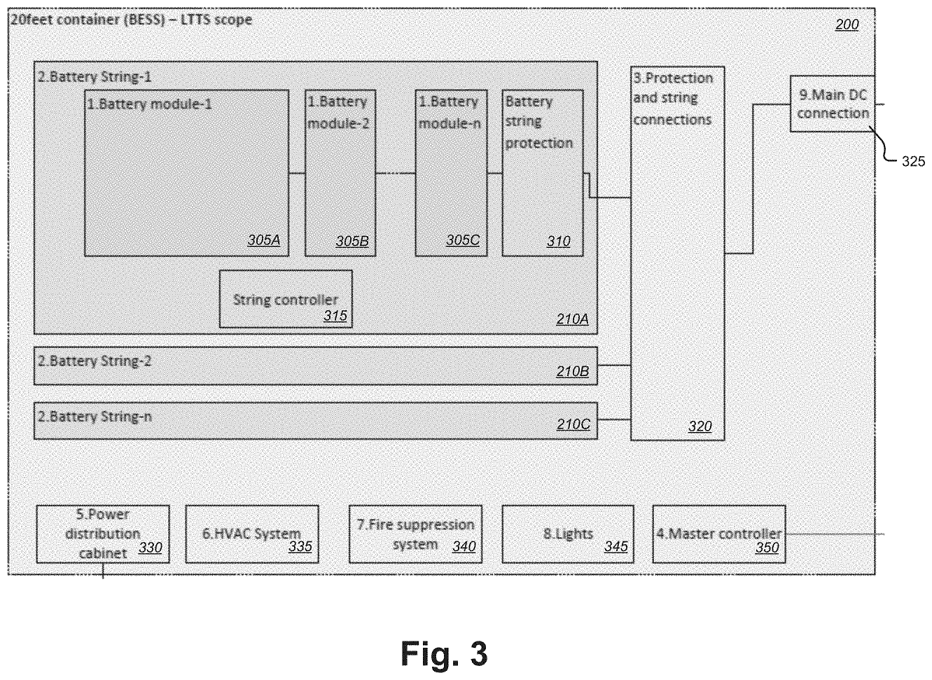

FIG. 3 is a block diagram illustrating components of an energy storage platform according to one embodiment of the present disclosure. As noted above and as further illustrated here, the assembled electrical storage platform 200 can comprise a number of battery strings 210A-210C. Each battery string 210A-210C can comprise a number of battery modules 305A-305C, e.g., cells, electrical battery string protection circuits 310, e.g., over voltage and/or over current protection, and string controller circuits 315. As noted above, the battery modules 305A-305C can comprise different types of batteries including, but not limited to, lithium-ion, nickel-cadmium (NiCd), nickel-metal hydride (NiMh), lithium-ion polymer, lead-acid, and other batteries known to those skilled in the art. It should be understood that the various battery strings 210A-210C of the energy storage platform 200 can comprise battery modules of all the same type or one or more different types depending upon the exact implementations and without departing from the scope of the present disclosure. Regardless of the exact type of battery modules 305A-305C and/or number of battery strings 210A-210C used, the battery strings 210A-210C each can be further connected to protection circuits and string connections 320 which in turns provides electrical connection to the main DC bus or conductors 325 for the energy storage platform 200.

According to one embodiment, the assembled electrical storage platform 200 can comprise a number of other components. For example, the energy storage platform 200 can comprise a power distribution cabinet 330 for housing connections, switches, breakers, etc., for internal power distribution within the energy storage platform 200. Additionally or alternatively, the energy storage platform 200 can comprise a Heating Ventilation and Air Conditioning (HVAC) system 335 for controlling temperature within the energy storage platform 200. The energy storage platform 200 may additionally or alternatively comprise one or more of a fire suppression system 340, internal lighting 345, and/or a master controller 350. One or more additional or alternative other components are contemplated and also considered to be within the scope of the present disclosure.

Stated another way, an energy storage platform 200 can comprise a container 100. The container can comprise a bottom portion 110 forming a deck of the container, a top portion 105 disposed above the bottom portion 110 and forming a roof of the container 100, and four sides 115, 120A and 120B, 125A-125C, and 125D-125F extending from the bottom portion 110 of the container 100 to the top portion 105 of the container 100. The bottom portion 110, the four sides 115, 120A and 120B, 125A-125C, and 125D-125F, and the top portion 105 can form a substantially rectangular box substantially enclosing an interior portion of the container 100 with two parallel sides 125A-125C and 125D-125F of the four sides forming a length side of the rectangular box, and another two parallel sides 115 and 120A and 120B of the four sides forming a width side of the rectangular box, and wherein the length side of the rectangular box is longer than the width side. A central, internal gangway 205 on the deck 110 of the container 100 can extend a length of the container 100 substantially parallel to the two parallel sides 125A-125C and 125D-125F forming the length side of the rectangular box. A plurality of equipment racks can be disposed within the interior portion of the container 100. The equipment racks can be disposed substantially parallel and opposite to each other on each side of the gangway 205 and adjacent to the two parallel sides 125A-125C and 125D-125F forming the length side of the rectangular box. A plurality of battery strings 210A-210C, each battery string comprising a plurality of battery modules 305A-305C, can be mounted in the plurality of equipment racks.

The battery modules 305A-305C of each battery string 210A-210C can comprise a battery type, the battery type comprising one or more of lithium-ion, nickel-cadmium, nickel-metal hydride, lithium-ion polymer, or lead-acid. In some cases, at least one of the battery strings 210A can comprise battery modules of a different battery type from battery modules of one or more other battery strings 210B and/or 210C of the plurality of battery strings. In some cases, each battery string 210A-210C can further comprise one or more battery string protection circuits 310 and one or more battery string control circuits 315 mounted in the equipment racks.

Each battery string 210A-210C can be further connected with one or more protection circuits and battery string connections 320 and a main bus 325 or conductors for the energy storage platform 200. One or more other components mounted in one or more of the equipment racks. The one or more other components mounted in one or more of the equipment racks can comprise one or more of a power distribution cabinet 330, a Heating Ventilation and Air Conditioning (HVAC) system 335, a fire suppression system 340, internal lighting 345, or a master controller 350.

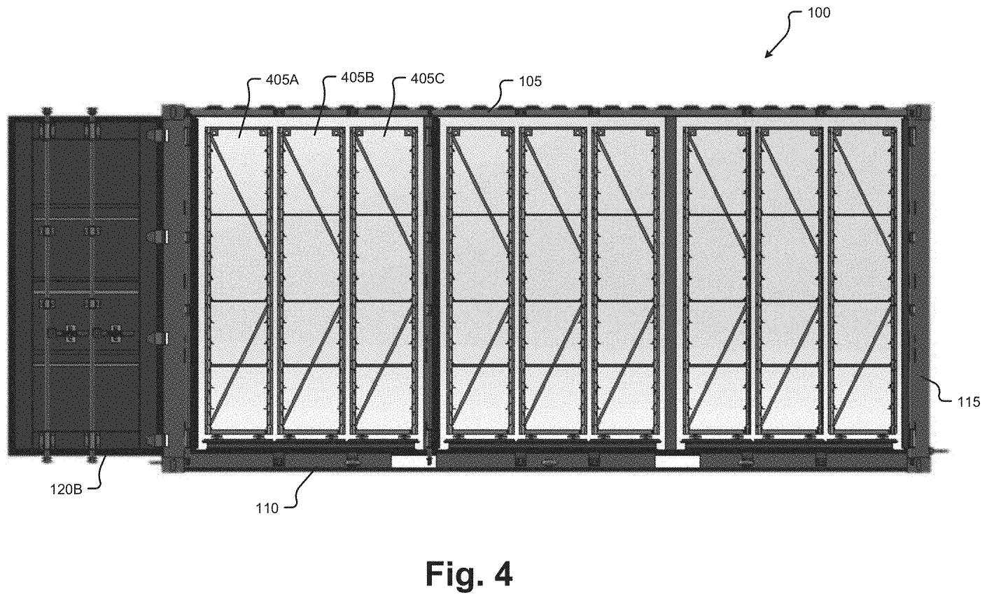

FIG. 4 is a diagram illustrating a cross-sectional side view of an energy storage platform container according to one embodiment of the present disclosure. As illustrated in this example and as described above, the container 100 can comprise a top portion 105 or roof, a bottom portion 110 or floor or deck, and four sides to enclose the contents of the container 100 when the energy storage platform is assembled. According to one embodiment, one or more sides of the container 100 may be fixed or sealed while other one or more sides may comprise doors or removeable covers or panels for assembly of the energy storage platform or to provide access to components within the container 100 after assembly. For example, one end 115 of the container 100 may be closed or sealed while another end, in this example the opposite end, can comprise a set of doors 120B through which the interior of the container 100 can be accessed.

The container 100 can also comprise a number of equipment racks 405A-405C disposed within the container 100, substantially parallel to each other, and on either side of the central, internal gangway 205, i.e., along and adjacent to the long sides of the container 100 as illustrated here. The racks 405A-405C can be accessed by the gangway 205 through the doors 120A and 120B at an end of the container 100. As described above, the racks 405A-405C can also be accessed through one or more doors 125A-125F along an outside of the container 100, i.e., along the long side of the container as illustrated here, and adjacent to the racks. The racks 405A-405C can be adapted to accept and retain one or more strings of batteries and other components of the energy storage platform when assembled. For example, the racks 405A-405C can comprise latches, ridges, shelves, ledges, bolts and/or bolt holes, threaded holes, clips, others fasteners and/or means for mounting and retaining the battery modules 305A-305C of the battery strings 210A-210C when installed in the racks 405A-405C. In some cases, the mounting and retaining features may be fixed but positioned to mount and retain battery modules of different types and/or sizes. In other cases, these features may be moveable, e.g., along horizontal and/or vertical struts or other supporting members of the racks 405A-405C, to adjust and to mount and retain battery modules of different types and/or sizes.

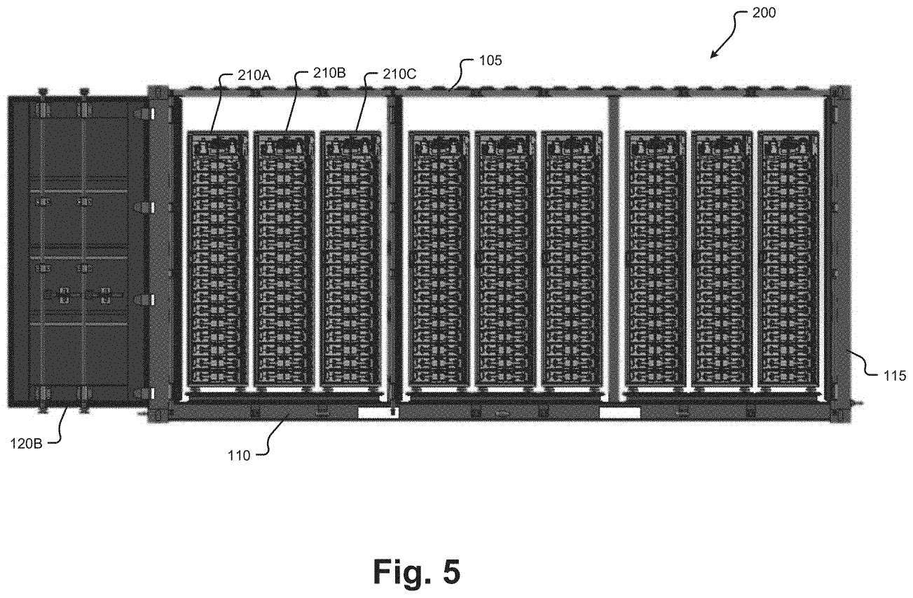

FIG. 5 is a diagram illustrating a cross-sectional side view of an energy storage platform according to another embodiment of the present disclosure. As illustrated in this example and as described above, can comprise a container 100 as described above, i.e., comprising a top portion 105 or roof, a bottom portion 110 or floor or deck, and four sides to enclose the contents of the container 100 when the energy storage platform is assembled. The container 100 can also comprise, as described above, a number of equipment racks 405A-405C disposed within the container 100, substantially parallel to each other, and on either side of the central, internal gangway 205, i.e., along and adjacent to the long sides of the container 100 as illustrated here. The racks 405A-405C can be adapted to accept and retain one or more strings of batteries 210A-210C and other components of the energy storage platform 200 when assembled. Also as described above, the racks can be adapted to mount and retain battery strings 210A-210C comprising battery modules of different types. The batteries used can be a variety of battery types including, but not limited to, lithium-ion, nickel-cadmium (NiCd), nickel-metal hydride (NiMh), lithium-ion polymer, lead-acid, and other batteries known to those skilled in the art.

The present disclosure, in various aspects, embodiments, and/or configurations, includes components, methods, processes, systems, and/or apparatus substantially as depicted and described herein, including various aspects, embodiments, configurations embodiments, subcombinations, and/or subsets thereof. Those of skill in the art will understand how to make and use the disclosed aspects, embodiments, and/or configurations after understanding the present disclosure. The present disclosure, in various aspects, embodiments, and/or configurations, includes providing devices and processes in the absence of items not depicted and/or described herein or in various aspects, embodiments, and/or configurations hereof, including in the absence of such items as may have been used in previous devices or processes, e.g., for improving performance, achieving ease and\or reducing cost of implementation.

The foregoing discussion has been presented for purposes of illustration and description. The foregoing is not intended to limit the disclosure to the form or forms disclosed herein. In the foregoing Detailed Description for example, various features of the disclosure are grouped together in one or more aspects, embodiments, and/or configurations for the purpose of streamlining the disclosure. The features of the aspects, embodiments, and/or configurations of the disclosure may be combined in alternate aspects, embodiments, and/or configurations other than those discussed above. This method of disclosure is not to be interpreted as reflecting an intention that the claims require more features than are expressly recited in each claim. Rather, as the following claims reflect, inventive aspects lie in less than all features of a single foregoing disclosed aspect, embodiment, and/or configuration. Thus, the following claims are hereby incorporated into this Detailed Description, with each claim standing on its own as a separate preferred embodiment of the disclosure.

Moreover, though the description has included description of one or more aspects, embodiments, and/or configurations and certain variations and modifications, other variations, combinations, and modifications are within the scope of the disclosure, e.g., as may be within the skill and knowledge of those in the art, after understanding the present disclosure. It is intended to obtain rights which include alternative aspects, embodiments, and/or configurations to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

What is claimed is:

1. A container for an energy storage platform, the container comprising:
a bottom portion forming a deck of the container;
a top portion disposed above the bottom portion and forming a roof of the container;
four sides extending from the bottom portion of the container to the top portion of the container, wherein the bottom portion, the four sides, and the top portion form a substantially rectangular box substantially enclosing an interior portion of the container with two parallel sides of the four sides forming a length side of the rectangular box, and another two parallel sides of the four sides forming a width side of the rectangular box, and wherein the length side of the rectangular box is longer than the width side;
a central, internal gangway on the deck of the container and extending a length of the container substantially parallel to the two parallel sides forming the length side of the rectangular box; and
a plurality of equipment racks disposed within the interior portion of the container, the equipment racks disposed substantially parallel and opposite to each other on each side of the gangway and adjacent to the two parallel sides of the four sides forming the length side of the rectangular box, wherein the two parallel sides forming the length side of the rectangular box are lined with an electrical insulating material, wherein the plurality of equipment racks are adapted to accept a plurality of battery strings, wherein terminals and connectors of the battery strings, when mounted in the plurality of equipment racks, and conductors between each battery are located on a side of the equipment racks opposite the central, internal gangway and wherein the two parallel sides forming the length side of the rectangular box.

2. The container of claim 1, wherein one of the sides forming the width side of the rectangular box comprises a door providing access to the gangway and the interior of the container.

3. The container of claim 2, wherein at least one of the sides forming the length side of the rectangular box comprises one or more doors providing access to the equipment racks adjacent to the at least one of the sides.

4. The container of claim 3, wherein the one or more doors of the at least one of the sides forming the length side of the rectangular box comprises a plurality of doors.

5. The container of claim 1, wherein one or more of the racks are each adapted to accept and retain a plurality of different types of battery strings.

6. An energy storage platform comprising:
a container, the container comprising:
a bottom portion forming a deck of the container,
a top portion disposed above the bottom portion and forming a roof of the container,
four sides extending from the bottom portion of the container to the top portion of the container, wherein the bottom portion, the four sides, and the top portion form a substantially rectangular box substantially enclosing an interior portion of the container with two parallel sides of the four sides forming a length side of the rectangular box, and another two parallel sides of the four sides forming a width side of the rectangular box, and wherein the length side of the rectangular box is longer than the width side,
a central, internal gangway on the deck of the container and extending a length of the container substantially parallel to the two parallel sides forming the length side of the rectangular box, and
a plurality of equipment racks disposed within the interior portion of the container, the equipment racks disposed substantially parallel and opposite to each other on each side of the gangway and adjacent to the two parallel sides forming the length side of the rectangular box; and
a plurality of battery strings, each battery string comprising a plurality of battery modules mounted in one of the plurality of equipment racks, wherein terminals and connectors of each battery and conductors between each battery are located on a side of the equipment racks opposite the central, internal gangway and wherein the two parallel sides forming the length side of the rectangular box are lined with an electrical insulating material.

7. The energy storage platform of claim 6, wherein one of the sides forming the width side of the rectangular box comprises a door providing access to the gangway and the interior of the container.

8. The energy storage platform of claim 7, wherein at least one of the sides forming the length side of the rectangular box comprises one or more doors providing access to the equipment racks and battery strings adjacent to the at least one of the sides.

9. The energy storage platform of claim 8, wherein the one or more doors of the at least one of the sides forming the length side of the rectangular box comprises a plurality of doors.

10. The energy storage platform of claim 6, wherein the battery modules of each battery string comprise a battery type, the battery type comprising one or more of lithium-ion, nickel-cadmium, nickel-metal hydride, lithium-ion polymer, or lead-acid.

11. The energy storage platform of claim 10, wherein at least one of the battery strings comprises battery modules of a different battery type from battery modules of one or more other battery strings of the plurality of battery strings.

12. The energy storage platform of claim 6, wherein each battery string further comprises one or more battery string protection circuits and one or more battery string control circuits mounted in the equipment racks.

13. The energy storage platform of claim 12, wherein each battery string is further connected with one or more protection circuits, one or more battery string connections, and a main bus or conductors for the energy storage platform.

14. The energy storage platform of claim 6, further comprising one or more components mounted in one or more of the equipment racks.

15. The energy storage platform of claim 14, wherein the one or more components mounted in one or more of the equipment racks comprise one or more of a power distribution cabinet, a Heating Ventilation and Air Conditioning (HVAC) system, a fire suppression system, internal lighting, or a master controller.
